(19) United States
(12) Patent Application Publication
(10) Pub. No.: US 2015/0264830 A1
(43) Pub. Date: Sep. 17, 2015

(54) myFlashWrap - USB Flash Drive Case

(71) Applicant: Rebecca Lynn Banacki, Grand Blanc, MI (US)

(72) Inventor: Rebecca Lynn Banacki, Grand Blanc, MI (US)

(21) Appl. No.: 14/623,033

(22) Filed: Feb. 16, 2015

Related U.S. Application Data
(60) Provisional application No. 61/967,107, filed on Mar. 11, 2014.

(51) Int. Cl. H05K 5/02; B65D 25/20

(52) U.S. Cl. CPC H05K 5/0291; B65D 25/205; H05K 5/0226; H05K 5/0221

(57) ABSTRACT

A case for organizing and storing one or more portable storage devices more specifically USB flash drives. The case itself is compact in size and is a one piece blow molded PVC rectangular box with no bulky excess material and with a “living” hinged top flap which fastens together with the bottom half using a predetermined closure mechanism such as a snap. The main body will be comprised of an elongated rectangular compartment with individual inside attached sleeves that separate and hold each device securely in place. The inside top flap also provides ample space for optional labeling of each sleeve opening using various labeling methods such as removable adhesive labels or hand writing. The outside of the case will be produced using predetermined printed designs using a UV printing process.

### CROSS-REFERENCE TO RELATED APPLICATIONS

This application claims priority under Provisional Application Ser. No. 61/967,107 filed Mar. 11, 2014.

### STATEMENT REGARDING FEDERALLY SPONSORED RESEARCH OF DEVELOPMENT

“Not Applicable”

### REFERENCE TO SEQUENCE LISTING, A TABLE, OR A COMPUTER PROGRAM LISTING COMPACT DISC APPENDIX

“Not Applicable”

### BACKGROUND OF THE INVENTION

The present invention relates generally to a portable storage device case more specifically a case to store USB flash drives.

Most people these days have one or more USB flash drives to save computer files, photos, or songs via MP3s. I have about 4 myself and it gets frustrating to carry each one around loosely since they are constantly being misplaced, or ending up in the bottom of a purse or in a drawer nowhere to be found. The present invention fulfills a need to organize and store the USB flash drives when not being used. This invention is for a very small compact case made of PVC that organizes several USB flash drives and fits easily in pockets, purses or book bags. This case will separate each USB flash drive inside the case with individual sleeves to protect each USB flash drive from foreign elements. This case will also provide an area inside the top flap for labeling each sleeve opening. And lastly this invention will provide portable storage device cases in fun, colorful prints that will appeal to a wide range of audience.

Besides individual USB flash drives laying around loose, prior art today for organizing and storing USB flash drives are attached to a key chain, attached to a lanyard hung around ones neck, or in plain colored cases made of bulky fabric that are just too large and inconvenient to carry around. This invention is very compact in size with very minimum excess material which makes is very easy and convenient to hold and therefore transport. This invention also has a few additional options like inside sleeves to protect each USB flash drive, ample space for labeling each sleeve, and is produced in many printed colorful designs.

The solution for this lack of existence, convenience and style is the invention of “myFlashWrap”, a case to organize and store portable storage devices preferably USB flash drives.

U.S. Patent Application 20130027868 (Villa-Real) discloses a practical multi-purpose color-coded flash drive organizer with compartmentalized separate memory sectors for enhanced efficiency and better effective anti-confusion performances in global personal, educational, professional, business and organizational works.

U.S. Patent Application 20130270126 (Oliver) discloses a case for holding portable digital devices

U.S. Patent Application 20120261280 (Hall) discloses a memory box for holding and transporting a plurality of substantially planar objects, such as photographs, along with a CD or DVD and/or a memory card or multiple memory cards.

U.S. Patent Application 20120206874 (Huang) discloses a multifunctional universal series bus flash drive organizer.

U.S. Pat. No. 6,644,488 (Coleman) discloses a combination gum and mint caddy for carrying gum and mints.

### BRIEF SUMMARY OF THE INVENTION

The primary objective of the present invention is to provide an easier more convenient way to organize, store, and therefore transport portable storage devices preferably USB flash drives while not in use.

myFlashWrap® is a small compact protective case to organize and store one or more portable storage devices preferably USB flash drives are described herein.

myFlashWrap® is one piece blow molded using PVC to form the elongated rectangular compartment comprised of a base and a “living’ hinged top flap that attaches both the top flap and the bottom base together with a predetermined closure mechanism.

myFlashWrap® has individual inside attached heat staked sleeves to keep each USB flash drive securely in place, organized, and protected from foreign elements.

myFlashWrap® also provides an area on the inside top flap for labeling each sleeve opening so as not to mix up similar looking USB flash drives being stored.

myFlashWrap® will provide predetermined print patterns using preferably a UV printing process allowing for several fun colorful options to appeal to a wide range of audience.

### BRIEF DESCRIPTION OF THE DRAWINGS

These and other features, aspects, and advantages of the present invention will become better understood with regard to the following description, appended claims, and accompanying drawings where:

FIG. 1 is a perspective view of myFlashWrap®, showing the case in the open position constructed in accordance with the present invention with one USB flash drive seated within an inside sleeve.

FIG. 2 is a perspective view of FIG. 1, showing myFlashWrap® in the closed position providing further detail of the present invention;

FIG. 3 is a perspective top view of FIG. 1, showing the inside embodiment of myFlashWrap®;

FIG. 4 is a perspective view of FIG. 1, showing the inside top flap of myFlashWrap®.

The present invention will be described in connection with a preferred embodiment, however, it will be understood that there is no intent to limit the invention to the embodiment described as someone skilled in the art might discover. On the contrary, the intent is to cover all alternatives, modifications, and equivalents as may be included within the scope of this invention as defined by the appended claims

Broken lines shown in the drawings are for illustrative purposes only and form no part of the claimed design.

### DETAILED DESCRIPTION OF THE INVENTION

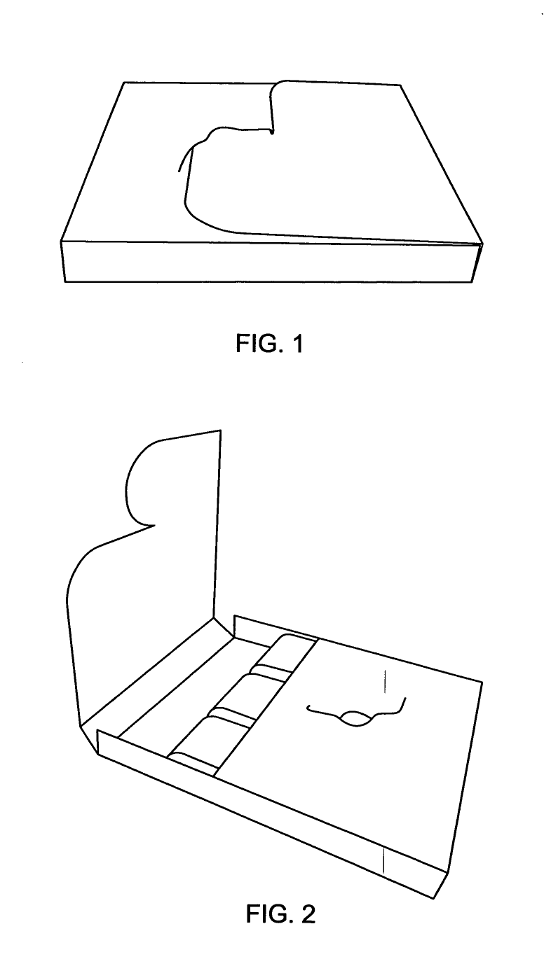

The preferred embodiments of the present invention will be described with reference to FIGS. 1-4 of the drawings. Identical elements in the various figures are identified with the same reference numbers.

FIG. 1 shows the present invention embodiment of myFlashWrap® 24 in the open position. In particular, FIG. 1 shows the case 24 which is an oblong rectangular compartment 50 comprising of three rectangular inside sleeves 32 that are suitable for storing up to three standard sized portable storage devices more specifically USB flash drives 52 in the upright position.

Although described herein as a case comprising of three rectangular inside sleeves to hold up to three USB flash drives, an alternative could be discovered to organize and store more which would be protected by this embodiment.

myFlashWrap® 24 further includes a top flap 38 that has 2 “living” hinge 34 that fold both sections 44 of the top flap 38.

The hinges 34 are “living” hinges molded from the same one piece unit as the case 24 using the same preferred PVC material as the embodied case 24.

The “living” hinges fold the small section of the flap 44 over the compartment 50 to cover the contents of the case 24 when closed. Alternative hinge designs could be used by someone skilled in the art but not shown as the preferred method.

Various materials may be used in forming myFlashWrap® 24 and its “living” hinged flap, including metals, plastics, fabric etc., but the preferred embodiment uses a plastic such as PVC that is blow molded. Further, it is contemplated that the case 24 will also be produced using a UV printing process after blow molding to apply predetermined colorful patterns along with solid colors to allow the user to several different fun and colorful options.

Opposite the hinged side there is a closure mechanism on the outside of the front of the case 24 as well as on the inside of the top flap 38 preferably a snap 36 to fasten the top flap 38 to the front of the case 24 together.

In the illustrated embodiment, the closing mechanism 36 is comprised of the “female” side of the snap fastener, while the “male” side of the snap fastener 40 is located on the interior surface of the flap 38. When the top flap 38 is closed, the stud or “male” side of the snap 40 interlocks with the socket or “female” side of the snap 36 and “locks” the flap closed.

It will be appreciated by those skilled in the art of container tooling and mold design that the configuration described above may be reversed, and that various equivalent closure method exist to permit the flap 38 of myFlashWrap® to be maintained in a closed position. Included in the alternatives are various flaps having a closure method like a snap made from other material like metal, Velcro®, magnet, elastic fastening system, or a slit cut into the described case 24.

Although described herein as a case for storing standard USB flash drives, alternative uses could be discovered which would be protected by this embodiment.

Also illustrated in FIG. 1 is the inside top flap 38 which provides ample space for optional labeling of the individual inside sleeves 32 which encase each USB flash drive 52.

FIG. 2 shows myFlashWrap® 24 in the closed position. Illustrated here the “living” hinges 34 fold the bottom of the top flap 44 over the main body of the case 24 allowing it to completely cover the compartment opening of the case 24, protecting the contents from foreign elements such as dust, dirt, or liquid etc. therefore attaching the top flap 38 to the bottom half of the case 24 using the closing mechanism 40 as described above.

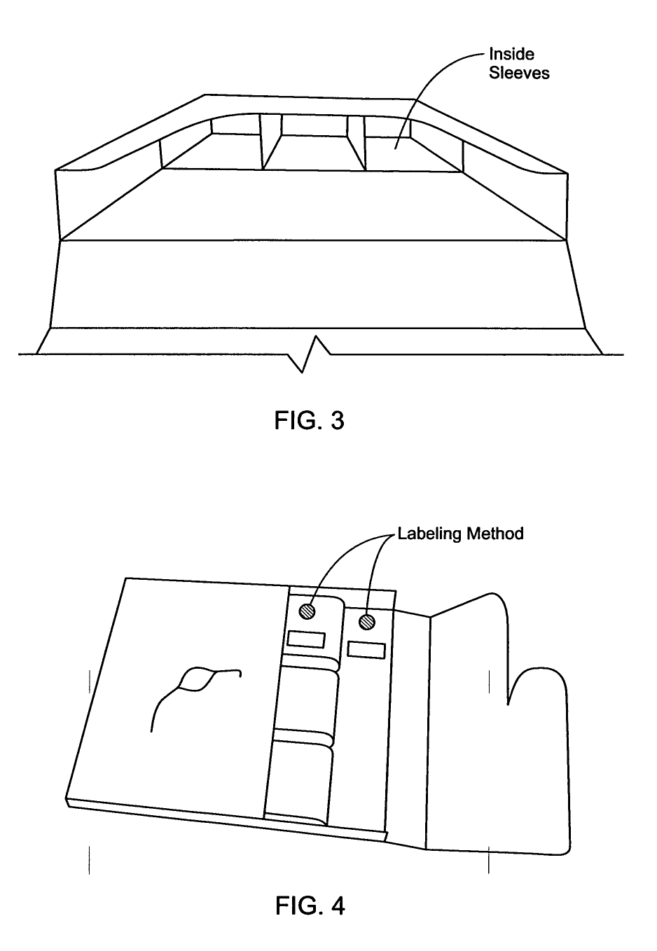

FIG. 3 is a detailed illustration of the top view of FIG. 1 showing the oblong rectangular compartment 50 with the preferred inside sleeves 32 that securely hold the portable storage devices more specifically USB flash drives 52 in place in an upright manner while being stored.

The inside sleeves 32 are made of the same molded material as myFlashWrap® 24 and will be attached preferably heat staked to the back of the inside of the case 24 preferably using a heat stake process.

FIG. 4 shows the top flap 38 of the case 24 illustrating the area for optional labeling 42.

In the preferred embodiment standard rectangular removable adhesive labels 42 are the desired method of labeling the inside sleeves 32, although someone skilled in the art may use various labels or other methods such as markers, etc.

Further each adhesive label 42 can be any size desired to fit the embodied top flab 38 including the section between each hinge 44, or the inside of the back of case 46.

1. myFlashWrap®, comprising: a case suitable for storing a plurality of portable storage devices preferably USB flash drives.

2. myFlashWrap® according to claim 1 in which the case is one piece blow molded PVC oblong rectangular compartment.

3. myFlashWrap® according to claim 1 in which there is a “living” hinge connecting the top half and the bottom half of the case together.

4. myFlashWrap® according to claim 1 in which the top flap closes over the case opening protecting the contents from foreign elements.

5. myFlashWrap® according to claim 1 in which a closure mechanism such as a snap attaches the top half to the bottom half of the case.

6. myFlashWrap® according to claim 1 in which the compartment includes individual sleeves to separate each portable storage device.

7. myFlashWrap® according to claim 1 in which the inside top flap has ample space for labeling each sleeve opening.

8. myFlashWrap® according to claim 1 in which the case is produced with printing in fun colorful patterns or design preferably using a UV printing process.
